(19) United States
(12) Patent Application Publication
(10) Pub. No.: US 2007/0072403 A1
(43) Pub. Date: Mar. 29, 2007

(54) Semiconductor device and method for fabricating the same

(75) Inventor: Toyokazu Sakata, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 11/526,698

(22) Filed: Sep. 26, 2006

(30) Foreign Application Priority Data
Sep. 27, 2005 (JP) 2005-279996

(51) Int. Cl. H01L 21/3205; H01L 21/4763

(52) U.S. Cl. 438/585

(57) ABSTRACT

A method for fabricating a semiconductor device includes the steps of forming a high-k layer insulating layer on a SOI substrate; forming a gate electrode layer on the high-k insulating layer; forming a resist layer on the gate electrode layer; removing selectively the gate electrode layer using the resist layer as a mask; and removing the resist layer by an ashing process using a gas that does not comprise oxygen.

### CROSS REFERENCE TO RELATED APPLICATION

This application claims the priority of Application No. 2005-279996, filed on Sep. 27, 2005 in Japan, the subject matter of which is incorporated herein by reference.

### TECHNICAL FIELD OF THE INVENTION

The present invention relates to a semiconductor device and a method for fabricating the same. Especially, the present invention relates to a method for a semiconductor device having a SOI (Silicon On Insulator) substrate and a high-k (high dielectric constant) gate insulating layer.

### BACKGROUND OF THE INVENTION

For instance, in an information communication field, a widespread of broad band technology brings with a requirement of a high performance system LSI, operating at a higher speed with a lower power consumption. Conventionally, for improving the performance of a system LSI, a gate length was shortened and a gate insulating layer (silicon oxide layer) was formed to be thinner. However, it becomes difficult to make a gate insulating layer thinner any more. Further, it becomes also difficult to reduce power consumption, because a tunnel leak current flowing through a gate insulating layer is increased.

Recently, a high-k film (layer) has been used instead of a silicon oxide layer as a gate insulating layer. Since a high-k film has a high dielectric constant, a high-k film can be formed to have a larger thickness easily as compared with a silicon oxide layer. Such a high-k film brings with lower power consumption and a higher driving power.

Japanese patent publication Tokkai 2004-327671A describes a method for forming a gate electrode using a SOI substrate and a high-k insulating layer. According to the invention described in the publication, a high-k film is formed on a SOI substrate, and a gate electrode is formed using a resist pattern. After that, the resist pattern is removed.

In more detail, an active region and an insulating region are formed on a SOI substrate by a device isolation technique, STI or LOCOS. After that, a High-k layer and a poly-silicon layer for a gate electrode are formed on the substrate. As a material for a High-k layer, an oxide metal may be used, for example, hafnium (Hf) and zirconium (Zr). A High-k layer is generally formed by a sputtering process, MOCVD (Metal Organic Chemical Vapor Deposition) process, ALCVD (Atomic Layer Chemical Vapor Deposition) process or MBE (Molecular Beam Epitaxy) process.

Next, a gate pattern is formed by a lithographic process, and a poly-silicon layer is dry-etched using the gate pattern as a mask. In the etching process, the High-k layer stops the etching proceeds. For an etching of a poly-silicon layer, generally, a chroride system or bromine system of halogen gas is used. In order to prevent a side etching and to obtain a sufficient selective rate relative to a gate insulating layer, a gas system generated by adding oxygen to a halogen gas, for example, Cl₂/O₂ or HBr/O₂ is used. Next, the resist is removed by an ashing process using O₂ plasma, and the High-k layer is removed by a wet-etching process. In the process of removing the High-k layer, an oxygen fluoride solution diluted by water (5% HF) may be used. After removing the High-k layer, processes of implantation, sidewall formation, silicon selective epitaxial growth, salicide treatment and wiring are carried out.

However, according to the above-described conventional method, oxygen radicals may get to a silicon layer, formed below the High-k layer in the gate etching process or the ashing process. As a result, a part of a surface of the silicon layer may possibly be reformed into an oxide layer. If a part of the SOI substrate is reformed into an oxide layer and the High-k layer is wet-etched with an oxygen fluoride solution, the oxidized part of the silicon layer would be removed together with the High-k layer. Recently, the thickness of a SOI substrate has become thinner and thinner in accordance with a higher performance of a semiconductor device. For example, according to “International Technology Roadmap for Semiconductors 2001 Edition (ITRS2001)”, a target value of the thickness of a SOI substrate is 20 nm in a generation of 130 nm node, and is 10 nm in a generation of 90 nm node. For that reason, a reformed silicon layer is possibly removed by an oxygen fluoride solution.

In general, a silicide reaction goes with a diffusion of silicon. If an enough amount of silicon is not remained, a silicide reaction would not be performed.

Further, if a part of a surface of a SOI layer is removed, the surface would become uneven; and as a result, a leak current would be generated between the gate electrode and an impurity diffused region (source/drain electrodes).

### OBJECTS OF THE INVENTION

Accordingly, an object of the present invention is to provide a method for fabricating a semiconductor device, in which a silicon layer, formed under a High-k gate insulating layer, is prevented from being reformed.

Another object of the present invention is to provide a method for fabricating a semiconductor device, a leak current is prevented from being generated between a gate electrode and an impurity diffused region (source/drain electrodes).

Additional objects, advantages and novel features of the present invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

According to the present invention, a method for fabricating a semiconductor device, comprising:

forming a high-k layer insulating layer on a SOI substrate;

forming a gate electrode layer on the high-k insulating layer;

forming a resist layer on the gate electrode layer;

removing selectively the gate electrode layer using the resist layer as a mask; and

removing the resist layer by an ashing process using a gas that does not comprise oxygen.

The gas for the ashing process may be a nitrogen gas (N₂), a hydrogen gas (H₂), ammonium gas (NH₃) or a combination of at least two of them. The gas for the ashing process may include a dilution gas. The dilution gas may be a gas selected one or more from argon (Ar), helium (He) and xenon (Xe).

The above described method according to the present invention further includes the step of: performing an etching process with a gas including no oxygen before the step of ashing process is carried out but after the high-k insulating layer is exposed by removing the gate electrode layer. The etching process may be carried out using a mixed gas of HBr and helium (He). A part of the gate electrode layer remaining on the high-k insulating layer may be removed after the etching process.

The above described method according to the present invention further includes the step of: performing a silicide process after the step of removing the high-k insulating layer.

The gate electrode layer may be made of poly-silicon.

The step of removing the high-k insulating layer may be carried out by a wet etching process using a oxygen fluoride solution.

The high-k insulating layer may be made a material selected from hafnium oxide (HfO₂), zirconia (ZrO₂), HfAlOx and HfSiONx.

### BRIEF DESCRIPTION OF THE DRAWINGS

FIG. 1 is cross-sectional views illustrating fabrication steps of a semiconductor device according to a first preferred embodiment of the present invention.

FIG. 2 is cross-sectional views illustrating fabrication steps of a semiconductor device according to a first preferred embodiment of the present invention, which follow the steps shown in FIG. 1.

FIG. 3 is cross-sectional views illustrating fabrication steps of a semiconductor device according to a first preferred embodiment of the present invention, which follow the steps shown in FIG. 2.

FIG. 4 is a cross-sectional view illustrating fabrication step of a semiconductor device according to a first preferred embodiment of the present invention, which follow the steps shown in FIG. 3.

FIG. 5 is cross-sectional views illustrating fabrication steps of a semiconductor device according to a second preferred embodiment of the present invention.

FIG. 6 is cross-sectional views illustrating fabrication steps of a semiconductor device according to a second preferred embodiment of the present invention, which follow the steps shown in FIG. 5.

### DESCRIPTION OF THE REFERENCE NUMERAL

110: silicon support substrate
112: buried oxide layer
114: silicon layer
116: High-k layer
118: poly-silicon layer
120: resist layer
124: sidewall
126: cobalt layer
128: silicide region
202: natural oxide layer
204: remained (remanent) poly-silicon

### DETAILED DISCLOSURE OF THE INVENTION

In the following detailed description of the preferred embodiments, reference is made to the accompanying drawings which form a part hereof, and in which is shown by way of illustration specific preferred embodiments in which the inventions may be practiced. These preferred embodiments are described in sufficient detail to enable those skilled in the art to practice the invention, and it is to be understood that other preferred embodiments may be utilized and that logical, mechanical and electrical changes may be made without departing from the spirit and scope of the present inventions. The following detailed description is, therefore, not to be taken in a limiting sense, and scope of the present inventions is defined only by the appended claims.

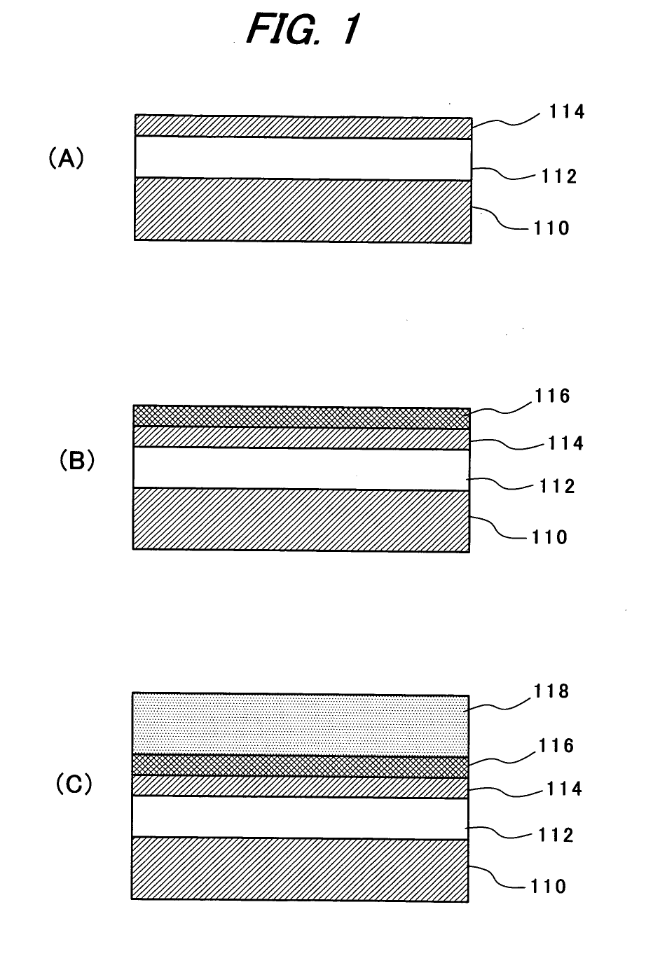

FIGS. 1-4 are cross-sectional view showing fabrication steps of a semiconductor device according to a first preferred embodiment of the present invention. As shown in FIG. 1(A), a SOI (silicon on insulator) substrate, including a silicon supporting substrate 110, a buried oxide layer (SiO₂ layer) and a silicon layer 114, is prepared. Next, the SOI substrate is isolated into active regions and insulating regions by a conventional device isolation manner, for example, STI or LOCOS.

Next, as shown in FIG. 1(B), a High-k layer 116 is formed on the silicon layer 114. As a material for the High-k layer 116, an oxide metal may be used, for example, hafnium (Hf) and zirconium (Zr), and also HfAlOₓ and HfSiONₓ. The High-k layer 116 is formed by a sputtering process, MOCVD (Metal Organic Chemical Vapor Deposition) process, ALCVD (Atomic Layer Chemical Vapor Deposition) process or MBE (Molecular Beam Epitaxy) process.

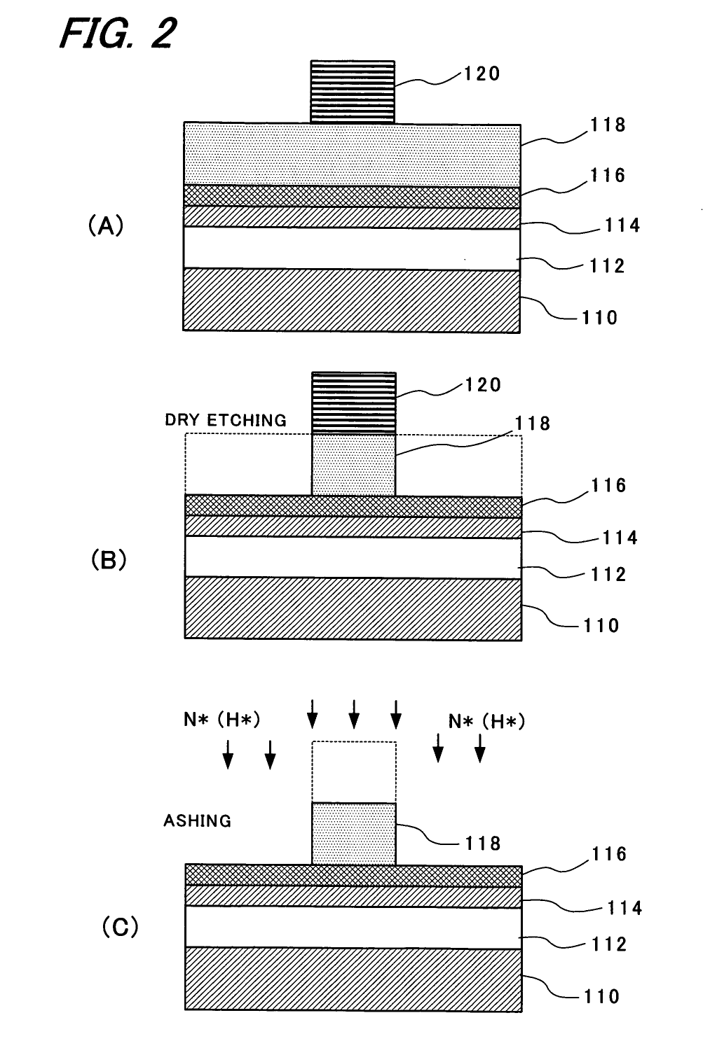

After that, as shown in FIG. 1(C), a poly-silicon layer 118 for a gate electrode is formed on the High-k layer 116. Next, as shown in FIG. 2(A), a resist pattern 120 for a gate electrode is formed on the poly-silicon layer 118. Next, as shown in FIG. 2(B), the poly-silicon layer 118 is dry-etched using the resist pattern 120 as a mask. The etching process is stopped on a surface of the High-k layer 116. For etching the poly-silicon layer 118, generally, a chroride system or bromine system of halogen gas is used. In order to prevent a side etching and to obtain a sufficient selective rate relative to a gate insulating layer, a gas system generated by adding oxygen to a halogen gas, for example, Cl₂/O₂ or HBr/O₂ is used.

Next, as shown in FIG. 2 (C), the resist pattern 120 is removed by an ashing process using a predetermined gas. The gas for ashing may be a nitrogen gas (N₂), a hydrogen gas (H₂), ammonium gas (NH₃) or a combination of at least two of them.

The following is a processing condition of the above-described ashing process using NH₃ gas:

Machine: UHF-ECR (plasma processing apparatus)

Gas: NH3=200 sccm

Pressure: 4 Pa

RF power: 500W (source)/100W (antenna)/50W (bias)

Substrate Temperature: 20 degrees Celsius (centigrade)

Where a resist etching rate and uniformity are about 400 nm/min and ±8.3% (plus and minus 8.3%), respectively.

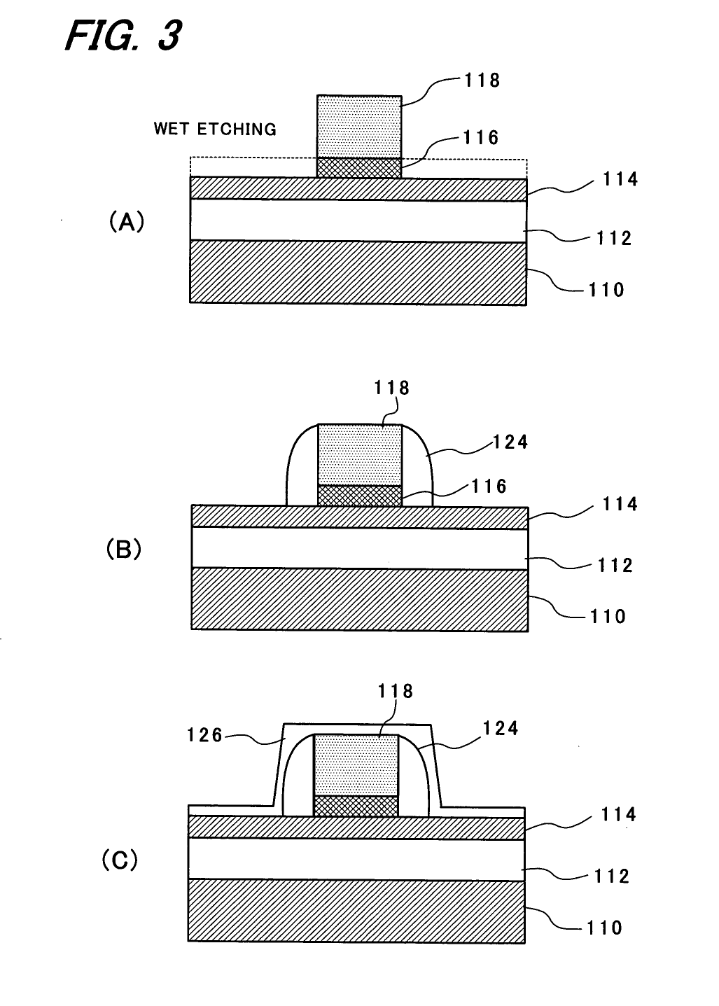

Next, as shown in FIG. 3(A), the High-k layer 116 is removed by a wet-etching process. In the wet-etching process, an oxygen fluoride solution diluted by water (5% HF) is used.

Next, a LDD (lightly doped drain) implantation process is carried out, and an insulating layer for a sidewall is formed. After that, as shown in FIG. 3(B), a sidewall 124 is formed by an etching-back process. Subsequently, ions, for example BF₂ (B) or P (As), are implanted to form source/drain regions. After that, a RTA (Rapid Thermal Annealing) process is carried out at 1000 degrees Celsius (centigrade) for activating the impurities.

Next, as shown in FIG. 3 (C), a silicide layer 126 of high melting metal is formed by a self-alignment technique in order to decrease a value of resistance of the gate electrode 118 and the diffusion layer (source/drain regions). In this embodiment, cobalt salicide (self aligned silicide) is used. The silicide layer 126 is formed by a sputtering process or a CVD (chemical vapor deposition) process so that Co/TiN laminated layer has a thickness of 50 Å/200 Å.

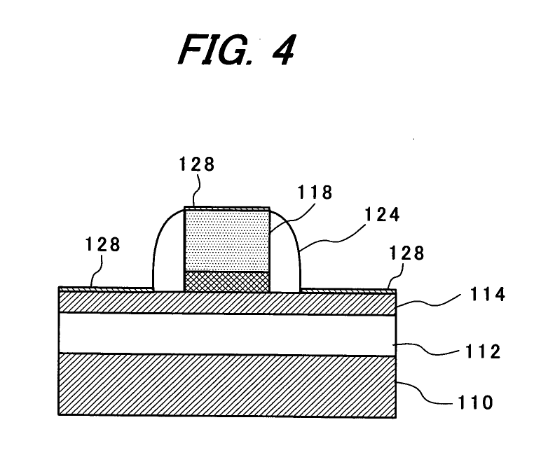

Next, a thermal treatment for silicide reaction and a selective etching process are carried out to remain a silicide layer only on the diffused layer (the gate electrode 118 and source/drain regions), as shown in FIG. 4. After that, an interlayer insulating layer is formed, a contact is formed and a multilayered wiring process is carried out.

As described above, according to the first preferred embodiment of the present invention, the resist formed on the High-k gate insulating layer 116 is removed by a plasma process using a gas including no oxygen, so that the silicon layer 114 formed under the High-k layer 116 is prevented from being oxidized. As a result, the silicon layer 114 is not removed in the following wet-etching process using oxygen fluoride solution; and therefore, only the High-k layer 116 can be removed. A sufficient amount of silicon can be remained for the following epitaxial growth process of the silicon layer at the source/drain regions and silicide process, so that those processes are carried out stably. A sufficient amount of silicon is remained for a silicide process, so that the silicide process can be carried out properly. Further, a surface of the SOI layer is not removed or reduced and the SOI substrate maintains a flat surface, so that a leak current could be prevented from being generated between the gate electrode and the diffused regions (source/drain electrodes).

According to the above-described first preferred embodiment, a single gas, such as nitrogen (N₂) and hydrogen (H₂), or a combination gas is used for an ashing process to remove the resist pattern 120. Argon (Ar) can be added to such an ashing gas. Preferably, a flow ration of Ar/(N₂+H₂+Ar) is determined in a range of 0.1 to 0.9.

When argon (Ar) gas is added as a dilution gas to an ashing gas for an ashing process removing the resist pattern 120, a dissociated efficiency of nitrogen (N₂) and hydrogen (H₂) would be improved; and therefore, the resist pattern 120 could be removed for a shorter period of time. Since no oxygen is added to the ashing gas, the silicon layer 114 formed under the High-k layer 116 is prevented from being reformed.

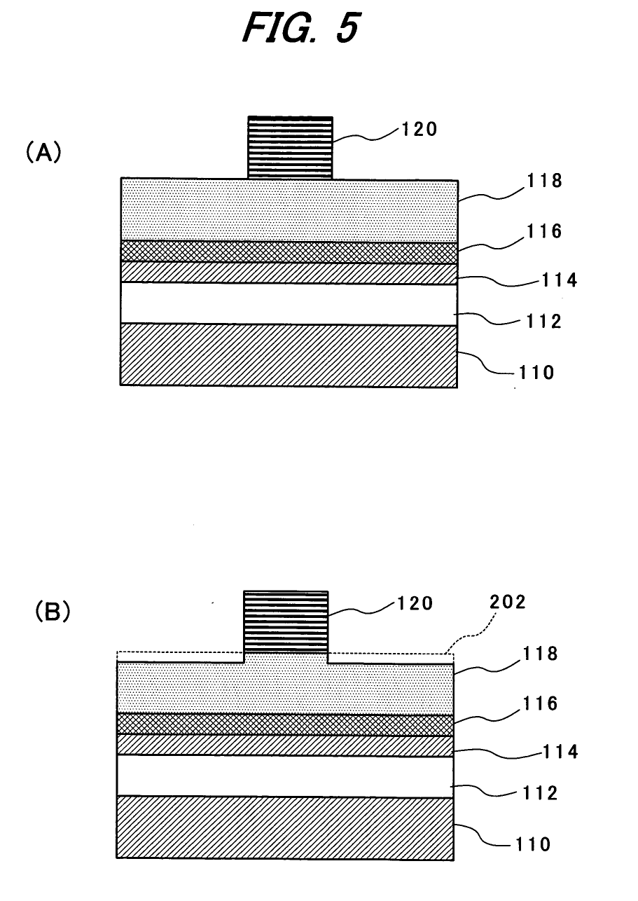

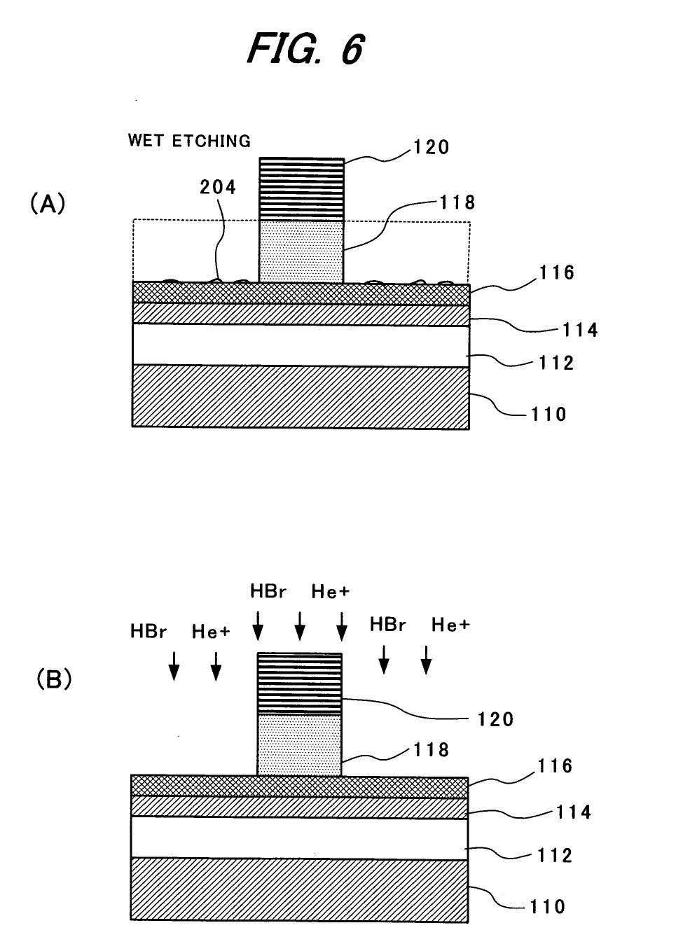

FIGS. 5 and 6 are cross-sectional views illustrating major fabrication steps of a semiconductor device according to a second preferred embodiment of the present invention. Fabrication steps of the first preferred embodiment are applicable to steps until FIG. 5(A) of the second preferred embodiment. The same description is not repeated herein. A poly-silicon layer 118 is etched using a gate patter (resist pattern) 120, formed by a photo-lithographic process, as a mask. Such etching process include three steps of (step 1) removing a natural oxide layer 202 shown in FIG. 5(B); (step 2) etching the poly-silicon layer 118 shown in FIG. 6(A); and (step 3) etching a gate insulating layer at a high selective ratio shown in FIG. 6(B).

The step shown in FIG. 6(B) is for removing a remained poly-silicon, which is not removed completely in the step 2 shown in FIG. 6(A). Step 3 is carried out under a condition in that the High-k layer 116 is exposed.

A feature of the second preferred embodiment is that step 3 is carried out using a gas including no oxygen. In the process of step 3, the following processing condition is applicable for high selective ration relative to a gate insulating layer:

Machine: Inductive Coupling Plasma (TCP) processing apparatus

Gas: HBr/He=100/100 sccm

Pressure: 60 mtorr

RF power: TCP/Bot=250/50W

Substrate Temperature: 60 degrees Celsius (centigrade)

Other processes after FIG. 6(B) are corresponding to those in the first preferred embodiment, and the same description is not repeated herein.

As described above, according to the second preferred embodiment of the present invention, an etching process is carried out using a gas including no oxygen under a condition in that the High-k layer 116 is exposed, so that the silicon layer 114 formed under the High-k layer 116 is prevented from being oxidized caused by oxygen radicals. As compared to the conventional technology, the silicon layer 114 is prevented from being removed in the process of removing the High-k layer 116. In addition, the advantages of the first preferred embodiment can be obtained by the second preferred embodiment as well.

What is claimed is:

1. A method for fabricating a semiconductor device, comprising:
forming a high-k layer insulating layer on a SOI substrate;
forming a gate electrode layer on the high-k insulating layer;
forming a resist layer on the gate electrode layer;
removing selectively the gate electrode layer using the resist layer as a mask; and
removing the resist layer by an ashing process using a gas that does not comprise oxygen.

2. A method for fabricating a semiconductor device according to claim 1, wherein
the gas for the ashing process is a nitrogen gas (N₂), a hydrogen gas (H₂), ammonium gas (NH₃) or a combination of at least two of them.

3. A method for fabricating a semiconductor device according to claim 1, wherein
the gas for the ashing process comprises a dilution gas.

4. A method for fabricating a semiconductor device according to claim 3, wherein
the dilution gas is a gas selected one or more from argon (Ar), helium (He) and xenon (Xe).

5. A method for fabricating a semiconductor device according to claim 1, further comprising:
performing an etching process with a gas including no oxygen before the step of ashing process is carried out but after the high-k insulating layer is exposed by removing the gate electrode layer.

6. A method for fabricating a semiconductor device according to claim 5, wherein
the etching process is carried out using a mixed gas of HBr and helium (He).

7. A method for fabricating a semiconductor device according to claim 5, further comprising:
removing a part of the gate electrode layer remaining on the high-k insulating layer after the etching process.

8. A method for fabricating a semiconductor device according to claim 1, further comprising:
performing a silicide process after the step of removing the high-k insulating layer.

9. A method for fabricating a semiconductor device according to claim 1, wherein
the gate electrode layer is made of poly-silicon.

10. A method for fabricating a semiconductor device according to claim 1, wherein
the step of removing the high-k insulating layer is carried out by a wet etching process using a oxygen fluoride solution.

11. A method for fabricating a semiconductor device according to claim 1, wherein
the high-k insulating layer is made a material selected from hafnium oxide (HfO₂), zirconia (ZrO₂), HfAlOₓ and HfSiONₓ.

12. A method for fabricating a semiconductor device, comprising:
forming a high-k layer insulating layer on a SOI substrate;
forming a poly-silicon layer for a gate electrode on the high-k insulating layer;
forming a resist layer on the poly-silicon layer;
removing selectively the poly-silicon layer using the resist layer as a mask;
removing the resist layer by an ashing process using a gas that does not comprise oxygen;
performing a wet etching process to remove selectively the high-k insulating layer so as to form a gate insulating layer;
forming source/drain regions; and
forming a silicide region on the gate electrode and source/drain regions.

13. A method for fabricating a semiconductor device according to claim 12, wherein
the gas for the ashing process is a nitrogen gas (N₂), a hydrogen gas (H₂), ammonium gas (NH₃) or a combination of at least two of them.

14. A method for fabricating a semiconductor device according to claim 12, wherein
the gas for the ashing process comprises a dilution gas.

15. A method for fabricating a semiconductor device according to claim 14, wherein
the dilution gas is a gas selected one or more from argon (Ar), helium (He) and xenon (Xe).

16. A method for fabricating a semiconductor device according to claim 12, further comprising:
performing an etching process with a gas including no oxygen before the step of ashing process is carried out but after the high-k insulating layer is exposed by removing the gate electrode layer.

17. A method for fabricating a semiconductor device according to claim 16, wherein
the etching process is carried out using a mixed gas of HBr and helium (He).

18. A method for fabricating a semiconductor device according to claim 16, further comprising:
removing a part of the gate electrode layer remaining on the high-k insulating layer after the etching process.

19. A method for fabricating a semiconductor device according to claim 12, wherein
the high-k insulating layer is made a material selected from hafnium oxide (HfO₂), zirconia (ZrO₂), HfAlOx and HfSiONx.

20. A semiconductor device fabricated by a method according to claim 1.

21. A semiconductor device fabricated by a method according to claim 12.
